(19) United States
(12) Patent Application Publication
(10) Pub. No.: US 2011/0163460 A1
(43) Pub. Date: Jul. 7, 2011

(54) Thermally Conductive Silicone Composition And Semiconductor Device

(75) Inventors: Tomoko Kato, Ichihara-shi (JP); Kazumi Nakayoshi, Sodegaura-shi (JP)

(73) Assignee: DOW CORNING TORAY CO., LTD., Tokyo (JP)

(21) Appl. No.: 13/061,627

(22) PCT Filed: Aug. 20, 2009
(86) PCT No.: PCT/JP2009/064901

§ 371 Date: Mar. 1, 2011

(30) Foreign Application Priority Data
Sep. 1, 2008 (JP) 2008-223588

(51) Int. Cl. H01L 23/29; C09K 5/00

(52) U.S. Cl. 257/791; 252/78.3; 257/E23.12

(57) ABSTRACT

A thermally conductive silicone composition comprises (A) an organopolysiloxane having a viscosity equal to or greater than 100 mPa·s at 25° C.; (B) aluminum powder having an average size of particles ranging from 0.1 to 100 μm; (C) zinc oxide powder having an average size of particles ranging from 0.05 to 50 μm; (D) (i) an organopolysiloxane containing univalent hydrocarbon groups which have unsaturated aliphatic bonds, (ii) an organopolysiloxane containing hydrocarbon groups which are free of unsaturated aliphatic bonds, or a mixture of constituents (i) and (ii); and (E) a silane compound or a product of partial hydrolyzation and condensation of said silane compound. The composition has high conductivity and excellent handleability.

### TECHNICAL FIELD

The present invention relates to a thermally conductive silicone composition and to a semiconductor device that employs this composition.

### BACKGROUND ART

In recent years, following an increase in the degree of density and integration of hybrid ICs and printed circuit boards that carry transistors, ICs, memory elements, and other electronic components, various thermally conductive silicone greases, thermally conductive silicone gel compositions, thermally conductive silicone rubber compositions, or other thermally conductive silicone compositions have been used in order to achieve efficient heat dissipation from such devices. For improving thermal conductivity of such compositions, they have to be filled with thermally conductive fillers to a high degree of filling. For example, Japanese Unexamined Patent Application Publication (hereinafter referred to as “Kokai”) 2000-256558 discloses a thermally conductive silicone rubber composition comprising: an organopolysiloxane, a methylpolysiloxane containing hydrolysable groups, a thermally conductive filler, and a curing agent. Furthermore, Kokai 2001-139815 discloses a thermally conductive silicone rubber composition comprising: a curable organopolysiloxane, a curing agent, and a thermally conductive filler, wherein the surface of the filler is treated with an oligosiloxane containing silicon-bonded alkoxy groups. Kokai 2003-213133 discloses a thermally conductive silicone rubber composition of improved thermal conductivity, wherein the composition comprises an organopolysiloxane containing in one molecule on average 0.1 or more silicon-bonded alkenyl groups, an organopolysiloxane containing in one molecule on average two or more silicon-bonded hydrogen atoms, a thermally conductive filler, a platinum type metal based catalyst, and a methylpolysiloxane containing hydrolysable groups and vinyl groups.

Furthermore, recent increase in density and integration degree of electronic devices has led to a demand for thermally conductive silicone compositions that would possess higher thermal conductivity than conventional compositions of this type.

However, increase in the content of the thermally conductive filler in the composition noticeably impairs handleability and application properties of the obtained composition.

It is an object of the present invention to provide a thermally conductive silicone composition that possesses high thermal conductivity and excellent handleability. It is another object to provide a highly reliable semiconductor device that uses the aforementioned composition.

### DISCLOSURE OF INVENTION

The thermally conductive silicone composition of the invention comprises:

(A) 100 parts by mass of an organopolysiloxane having a viscosity equal to or greater than 100 mPa·s at 25° C.;

(B) 25 to 4,500 parts by mass of aluminum powder having an average size of particles ranging from 0.1 to 100 μm;

(C) 10 to 1,000 parts by mass of zinc oxide powder having an average size of particles ranging from 0.05 to 50 μm;

(D) (i) an organopolysiloxane represented by the following general formula:

[R¹ₐR²₍₃₋ₐ₎SiO(R¹_{b}R²_{(2-b)} SiO)ₘ(R²₂SiO)ₙ]_{c}SiR²_{[4-(c+d)]}(OR³)_{d} (where R¹ represents univalent hydrocarbon groups which have unsaturated aliphatic bonds; R² represents univalent hydrocarbon groups which are free of unsaturated aliphatic bonds; R³ represents groups selected from alkyl groups, alkoxyalkyl groups, alkenyl groups, or acyl groups; “a” is an integer ranging from 0 to 3; “b” is 1 or 2; “c” is an integer ranging from 1 to 3; “d” is an integer ranging from 1 to 3; “(c+d)” is an integer ranging from 2 to 4; “m” is an integer equal to or greater than 0; “n” is an integer equal to or greater than 0; however, when “a” is equal to 0, “m” is an integer equal to or greater than 1); and/or (ii) an organopolysiloxane represented by the following general formula:

R²₃SiO(R²₂SiO)ₚR²₂Si—R⁴—SiR²_{(3-d)}(OR³)_{d}

(where R², R³, and “d” are the same as defined above, R⁴ represents an oxygen atom or bivalent hydrocarbon group; and “p” is an integer ranging from 100 to 500) {this component being used in an amount of 0.01 to 100 parts by mass per 100 parts by mass of the sum of components (B) and (C)}; and

(E) a silane compound of the following general formula or a product of partial hydrolyzation and condensation of said silane compound:

R⁵ₑSi(OR⁶)₍₄₋ₑ₎

(where R⁵ represents univalent hydrocarbon groups, epoxy-containing organic groups, methacryl-containing organic groups, or acryl-containing organic groups; R⁶ represents alkyl groups or alkoxyalkyl groups; and “e” is an integer ranging from 1 to 3) {this component being used in an amount of 0.001 to 10 parts by mass per 100 parts by mass of the sum of components (B) and (C)}.

It is recommended that component (A) of the composition be comprised of an organopolysiloxane that contains in one molecule on average 0.1 or more silicon-bonded alkenyl groups. In this case, to make the composition curable, it is desirable that the composition further comprises (F) an organopolysiloxane having in one molecule on average two or more silicon-bonded hydrogen atoms {this component being used in such an amount that the content of the silicon-bonded hydrogen atoms contained in this component ranges from 0.1 to 10 moles per 1 mole of the silicon-bonded alkenyl groups contained in component (A)}; and (G) a platinum type metal based catalyst {this component being used in such an amount that, in terms of mass units, the content of platinum type metal in this component ranges from 0.01 to 1,000 ppm per mass of the sum of components (A) and (F)}

It is recommended that in the above composition component (B) be comprised a mixture prepared from aluminum powders of at least two types that have a difference in average particle sizes equal to or is greater than 5 μm. And it is recommended that, in terms of mass units, the ratio of component (B) to component (C) ranges from 0.1 to 9.9.

A semiconductor device of the invention contains a semiconductor chip attached to, or coated with, the aforementioned thermally conductive silicone composition.

### Effects of Invention

The thermally conductive silicone composition of the invention is efficient in that it possesses high thermal conductivity and good handleability. The semiconductor device of the invention is characterized by excellent reliability.

### BRIEF DESCRIPTION OF THE DRAWINGS

FIG. 1 shows an LSI as an example of a semiconductor device of the invention.

### REFERENCE NUMERALS USED IN THE DESCRIPTION

1 semiconductor chip
2 circuit board
3 circuit
4 bonding wire
5 thermally conductive composition (or a cured body of the composition)
6 heat-dissipating member

### DETAILED DESCRIPTION OF THE INVENTION

The thermally conductive silicone composition of the invention will now be described in more details.

The organopolysiloxane that constitutes component (A) is one of the main components of the composition. This component has a viscosity at 25° C. equal to or greater than 100 mPa·s, preferably a viscosity ranging from 100 to 1,000,000 mPa·s, more preferably from 200 to 500,000 mPa·s, and most preferably from 300 to 100,000 mPa·s. If the viscosity of component (A) at 25° C. is below the recommended lower limit, this will facilitate oil bleeding from the composition. If, on the other hand, the viscosity exceeds the recommended upper limit, this will impair handleability of the obtained composition.

There are no special restrictions with regard to the molecular structure of component (A). For example, this component may have a linear, branched, partially branched linear, or a dendritic molecular structure. The linear and partially branched linear molecular structures are preferable. The aforementioned molecular structures may be present in component (A) as a homopolymer, copolymer, or a mixture of these polymers. The silicon-bonded groups of component (A) may be exemplified by methyl, ethyl, propyl, butyl, pentyl, hexyl, heptyl, octyl, nonyl, decyl, undecyl, dodecyl, tridecyl, tetradecyl, pentadecyl, hexadecyl, heptadecyl, octadecyl, nonadecyl, eicosyl, or similar linear-chain alkyl groups; isopropyl, tertiary butyl, isobutyl, 2-methylundecyl, 1-hexylheptyl, or similar branched-chain alkyl groups; cyclopentyl, cyclohexyl, cyclododecyl, or similar cyclic alkyl groups; vinyl, allyl, butenyl, pentenyl, hexenyl, or similar alkenyl groups; phenyl, tolyl, xylyl, or similar aryl groups; benzyl, phenethyl, 2-(2,4,6-trimethylphenyl)propyl, or similar aralkyl groups; and 3,3,3-trifluoropropyl, 3-chloropropyl, or similar halogenated alkyl groups. Most preferable are alkyl, alkenyl, and aryl groups, especially methyl, vinyl, and phenyl groups. In order to obtain a composition of good curability, it is recommended that component (A) contains in one molecule on average 0.1 or more silicon-bonded alkenyl groups.

Component (A) may be exemplified by the following specific compounds: a dimethylpolysiloxane capped at both molecular terminals with trimethylsiloxy groups; a dimethylpolysiloxane capped at both molecular terminals with dimethylvinylsiloxy groups; a dimethylpolysiloxane capped at both molecular terminals with methylphenylvinylsiloxy groups; a copolymer of a methylphenylsiloxane and a dimethylsiloxane capped at both molecular terminals with trimethylsiloxy groups; a copolymer of a methylinylsiloxane and a dimethylsiloxane capped at both molecular terminals with dimethylvinylsiloxy groups; a copolymer of a methylvinylsiloxane and a dimethylsiloxane capped at both molecular terminals with trimethylsiloxy groups; a copolymer of a methylvinylsiloxane and a dimethylsiloxane capped at both molecular terminals with dimethylvinylsiloxy groups; a copolymer of a methylvinylsiloxane and a dimethylsiloxane capped at both molecular terminals with trimethylsiloxy groups; a methyl (3,3,3-trifluoropropyl) polysiloxane capped at both molecular terminals with dimethylvinylsiloxy groups; a dimethylsiloxane capped at both molecular terminals with silanol groups; a copolymer of a methylphenylsiloxane and a dimethylsiloxane capped at both molecular terminals with silanol groups; an organosiloxane copolymer composed of siloxane units represented by the following unit formulae: CH₃SiO_{3/2} and (CH₃)₂SiO_{2/2}; an organosiloxane copolymer composed of siloxane units represented by the following unit formulae: C₆H₅SiO_{3/2} and (CH₃)₂SiO_{2/2}; an organosiloxane copolymer composed of siloxane units represented by the following unit formulae: (CH₃)₃SiO_{1/2}; CH₃SiO_{3/2}; and (CH₃)₂SiO_{2/2}; an organosiloxane copolymer composed of the siloxane units represented by the following unit formulae: (CH₃)₃SiO_{1/2}; (CH₃)₂(CH₂═CH) SiO_{1/2}; CH₃SiO_{3/2}; and (CH₃)₂SiO_{2/2}; or combinations of two or more of the above compounds.

The aluminum powder that constitutes component (B) is intended for imparting thermal conductivity to the composition. There are no special restrictions with regard to the shape of component (B) particles that may have a spherical, roundish, flake-like, or irregular shape, of which spherical and roundish shapes are preferable. The average size of component (B) particles ranges from 0.1 to 100 μm, preferably from 0.1 to 50 μm.

Component (B) may comprise an aluminum powder of one type, but preferably, is composed of at least two types with a particle size difference of not less than 5

Component (B) is added to the composition in an amount of 25 to 4,500 parts by mass, preferably 50 to 4,000 parts by mass, and most preferably 100 to 3,000 parts by mass per 100 parts by mass of component (A). If the added amount of component (B) is below the recommended lower limit, the obtained silicone composition will not possess the required thermal conductivity. If, on the other hand, the added amount exceeds the recommended upper limit, this will impair handleability of the obtained silicone composition.

The zinc oxide powder that constitutes component (C) is also intended for imparting thermal conductivity to the composition. There are no special restrictions with regard to the shape of component (C) particles that may have a spherical, roundish, flakelike, or irregular shape. The average size of component (C) particles ranges from 0.05 to 50 μm, preferably from 0.1 to 50 μm.

Component (C) is added to the composition in an amount of 10 to 1,000 parts by mass, preferably 100 to 1,000 parts by mass, per 100 parts by mass of component (A). If the added amount of component (C) is below the recommended lower limit, the obtained silicone composition will not possess the required thermal conductivity. If, on the other hand, the added amount exceeds the recommended upper limit, this will impair handleability of the obtained silicone composition.

There are no special restrictions with regard to the ratio in which components (B) and (C) are used in the composition, but it may be recommended that, in terms of mass units, the ratio of component (B) to component (C) range from 0.1 to 9.9. If component (B) is used in an amount below the recommended lower limit, the obtained silicone composition will not possess the required thermal conductivity. If, on the other hand, the added amount of component (B) exceeds the recommended upper limit, this will impair handleability of the obtained silicone composition.

Component (D) is added for improving the thermal conductivity of the silicone composition and to provide possibility of using increased amounts of components (B) and (C) without impairing handleability of the composition. Component (D) is composed of (i) an organopolysiloxane represented by the following general formula:

[R¹ₐR²₍₃₋ₐ₎SiO(R¹_{b}R²_{(2-b)}SiO)ₘ(R²₂SiO)ₙ]_{c}SiR²_{[4-(c+d)]}(OR³)_{d}

and/or (ii) an organopolysiloxane represented by the following general formula:

R²₃SiO(R²₂SiO)ₚR²₂Si—R⁴—SiR²_{(3-d)}(OR³)_{d}.

In the organopolysiloxane of constituent (i), R¹ represents univalent hydrocarbon groups which have unsaturated aliphatic bonds and can be exemplified by vinyl, allyl, butenyl, hexenyl, decenyl, undecenyl, dodecenyl, tridecenyl, tetradecenyl, pentadcenyl, hexadecenyl, heptadecenyl, octadecenyl, nonadecenyl, eicosenyl, or a similar linear-chain alkenyl groups; isopropenyl, 2-methyl-2-propenyl, 2-methyl-10-undecenyl, and other branched alkenyl groups; vinylcyclohexyl, vinylcyclododecyl, and other cyclic alkyl groups having aliphatic unsaturated bonds; vinylphenyl, and other aryl groups having aliphatic unsaturated bonds; vinylbenzyl, vinylphenethyl, and other aralkyl groups having aliphatic unsaturated bond. Preferably, these groups are linear-chain groups, and especially preferably, vinyl, allyl, or hexenyl groups. There are no limitations concerning the position of the aliphatic unsaturated bonds in R¹, but it is preferably a position located far from the attached silicon atoms. In addition, R² in the formula above stands for univalent hydrocarbon groups that are free of aliphatic unsaturated bonds, exemplified by methyl, ethyl, propyl, butyl, pentyl, hexyl, heptyl, octyl, nonyl, decyl, undecyl, dodecyl, tridecyl, tetradecyl, pentadecyl, hexadecyl, heptadecyl, octadecyl, nonadecyl, eicosyl, or similar linear-chain alkyl groups; isopropyl, tertiary butyl, isobutyl, 2-methylundecyl, 1-hexylheptyl, or similar branched-chain alkyl groups; cyclopentyl, cyclohexyl, cyclododecyl, or similar cyclic alkyl groups; phenyl, tolyl, xylyl, or similar aryl groups; benzyl, phenethyl, 2-(2,4,6-trimethylphenyl)propyl, or similar aralkyl groups; and 3,3,3-trifluoropropyl, 3-chloropropyl, or similar halogenated alkyl groups. Most preferable are alkyl and aryl groups, especially alkyl groups with 1 to 4 carbon atoms, such as methyl and ethyl groups. In addition, R³ in the formula above stands for alkyl, alkoxyalkyl, alkenyl, or acyl groups. The alkyl groups of R³ are exemplified, e.g., by the same linear alkyl, branched alkyl, and cyclic alkyl groups as those mentioned above, preferably, by linear alkyl groups, and especially preferably, by methyl, ethyl, or propyl groups. In addition, the groups suggested as the alkoxyalkyl groups of R³ are, e.g., methoxyethoxy, ethoxyethoxy, or methoxypropoxy groups, with methoxyethoxy groups being preferable. In addition, the alkenyl groups of R³, are exemplified by the same alkenyl groups as those shown above for R¹, preferably by isopropenyl groups. In addition, the acyl groups of R³ include, e.g., acetoxy groups. In the above formula, “a” is an integer of 0 to 3, preferably 1. In addition, “b” in the formula above is 1 or 2, preferably 1. In addition, “c” in the formula above is an integer of 1 to 3, preferably 1, and “d” is an integer of 1 to 3, where 3 is preferable. The sum “(c+d)” in the formula above is an integer of 2 to 4. In addition, “m” in the formula above is an integer of 0 or greater. However, when “a” is 0, “m” is an integer of 1 or greater; “m” is preferably an integer of 0 to 500, more preferably, 1 to 500, even more preferably, of 5 to 500, further preferably 10 to 500, and most preferably 10 to 200. In the formula, “n” is an integer of 0 or greater; “n” is preferably an integer of 0 to 500, more preferably, 1 to 500, still more preferably, 5 to 500, even more preferably, 10 to 500, and most preferably, 10 to 200.

Constituent (i) is exemplified by organopolysiloxanes represented by the following formulae:
(CH₂═CH)(CH₃)₂SiO[(CH₃)₂SiO]₃Si(OCH₃)₃
(CH₂═CH)(CH₃)₂SiO[(CH₃)₂SiO]₅Si(OCH₃)₃
(CH₂═CHCH₂)(CH₃)₂SiO[(CH₃)₂SiO]₅Si(OCH₃)₃
(CH₂═CHCH₂CH₂CH₂CH₂)(CH₃)₂SiO[(CH₃)₂SiO]₅Si(OCH₃)₃
(CH₂═CH)(CH₃)₂SiO[(CH₃)₂SiO]₇Si(OCH₃)₃
(CH₂═CH)(CH₃)₂SiO[(CH₃)₂SiO]₇Si(OC₂H₅)₃
(CH₂═CHCH₂)(CH₃)₂SiO[(CH₃)₂SiO]₇Si(OCH₃)₃
(CH₂═CHCH₂CH₂CH₂CH₂)(CH₃)₂SiO[(CH₃)₂SiO]₇Si(OCH₃)₃
(CH₂═CH)(CH₃)₂SiO[(CH₃)₂SiO]₇SiCH₃ (OCH₃)₂
(CH₂═CH)(CH₃)₂SiO[(CH₃)₂SiO]₂₅Si(OCH₃)₃
(CH₂═CH)(CH₃)₂SiO[(CH₃)₂SiO]₂₇Si(OCH₃)₃
(CH₂═CHCH₂)(CH₃)₂SiO[(CH₃)₂SiO]₂₅Si(OCH₃)₃
(CH₂═CHCH₂CH₂CH₂CH₂)(CH₃)₂SiO[(CH₃)₂SiO]₂₅Si(OCH₃)₃
(CH₂═CH)(CH₃)₂SiO[(CH₃)₂SiO]₂₅Si(OC₂H₅)₃
(CH₂═CH)(CH₃)₂SiO[(CH₃)₂SiO]₂₇Si(OC₂H₅)₃
(CH₂═CH)(CH₃)₂SiO[(CH₃)₂SiO]₂₅SiCH₃(OCH₃)₂
(CH₂═CH)(CH₃)₂SiO[(CH₃)₂SiO]₅₀Si(OCH₃)₃
(CH₂═CH)(CH₃)₂SiO[(CH₃)₂SiO]₁₀₀Si(OCH₃)₃
(CH₂═CH)(CH₃)₂SiO[(CH₃)₂SiO]₁₅₀Si(OCH₃)₃
(CH₂═CHCH₂)(CH₃)₂SiO[(CH₃)₂SiO]₅₀Si(OCH₃)₃
(CH₂═CHCH₂CH₂CH₂CH₂)(CH₃)₂SiO[(CH₃)₂SiO]₅₀Si(OCH₃)₃
(CH₂═CH)(CH₃)₂SiO[(CH₃)₂SiO]₅₀Si(OC₂H₅)₃
(CH₂═CH)(CH₃)₂SiO[(CH₃)₂SiO]₅₀SiCH₃(OCH₃)₂
(CH₂═CH)(CH₃)₂SiO[(CH₃)₂SiO]₅[(CH₃){(CH₃O)₃SiC₂H₄}SiO]₁Si(CH₃)₃
(CH₂═CH)(CH₃)₂SiO[(CH₃)₂SiO]₅[(CH₃){(CH₃O)₃SiC₂H₄}SiO]₁Si(CH₃)₃
(CH₂═CH)(CH₃)₂SiO[(CH₃)₂SiO]₅[(CH₃){(CH₃O)₃SiC₂H₄}SiO]₁Si(OCH₃)₃
(CH₂═CH)(CH₃)₂SiO[(CH₃)₂SiO]₅[(CH₃){(CH₃O)₃SiC₂H₄}SiO]₁Si(OCH₃)₃

In the organopolysiloxane of constituent (ii), R² represents univalent hydrocarbon groups which do not have unsaturated aliphatic bonds and can be exemplified by linear-chain alkyl, branched-chain alkyl, cyclic alkyl, aryl, aralkyl, and halogenated alkyl groups, of which linear-chain alkyl groups, especially methyl groups, are preferable. In the above formula, R⁴ represents an oxygen atom or bivalent hydrocarbon group. Bivalent hydrocarbon group of R⁴ can be exemplified by methylene, ethylene, propylene, isopropylene, butylene, and other alkylene group; ethylenoxyethylene, ethylenoxypropylene, and other alkylenoxyalkylene group. Particularly preferably, R⁴ is an oxygen atom. In addition, R³ in the formula above is represented by the same groups as those mentioned above. In addition, “p” is an integer of 100 to 500, preferably, an integer of 105 to 500, more preferably, an integer of 110 to 500, and most preferably, an integer of 110 to 200. This is due to the fact that when “p” in the formula above is less than the recommended lower limit of the above-mentioned range, components (B) and (C) cannot be added in increased quantities. On the other hand, when the value of “p” exceeds the recommended upper limit of the above-mentioned range, the molecular volume bound by the surfaces of components (B) and (C) increases excessively, and addition of a large quantity of component (B) and (C) tends to become impossible. In particular, if the content of components (B) and (C) in the present composition is made extremely high, such as 80 vol. % or more, this trend becomes more conspicuous because the average distance between the particles of components (B) or (C) becomes shorter. In addition, “d” in the above formula is an integer of 1 to 3, preferably 3.

Constituent (ii) is exemplified by organopolysiloxanes represented by the following formulae:
(CH₃)₃SiO[(CH₃)₂SiO]₁₁₈(CH₃)₂Si—O—Si(OCH₃)₃
(CH₃)₃SiO[(CH₃)₂SiO]₁₂₅(CH₃)₂Si—O—Si(OCH₃)₃
(CH₃)₃SiO[(CH₃)₂SiO]₁₄₀(CH₃)₂Si—O—Si(OCH₃)₃
(CH₃)₃SiO[(CH₃)₂SiO]₁₆₀(CH₃)₂Si—O—Si(OCH₃)₃
(CH₃)₃SiO[(CH₃)₂SiO]₂₀₀(CH₃)₂Si—O—Si(OCH₃)₃
(CH₃)₃SiO[(CH₃)₂SiO]₃₀₀(CH₃)₂Si—C₂H₄—Si(OCH₃)₃
(CH₃)₃SiO[(CH₃)₂SiO]₁₁₈(CH₃)₂Si—O—SiCH₃(OCH₃)₂
(CH₃)₃SiO[(CH₃)₂SiO]₇₉[(CH₃)(C₆H₅)SiO]₃₀(CH₃)₂Si—O—Si(OCH₃)₃
(CH₃)₃SiO[(CH₃)₂SiO]₇₉[(C₆H₅)₂SiO]₃₀(CH₃)₂Si—O—Si(OCH₃)₃

Component (D) may be comprised of either constituent (i) or constituent (ii), but preferably should be added as a mixture of constituents (i) and (ii). Although there are no special restrictions with regard to the mass-unit ratio of constituents (i) and (ii), it may be recommended to provide this ratio in the range of (1:5) to (5:1).

In the composition of the invention, component (D) is contained in an amount of 0.01 to 100 parts by mass, preferably 0.05 to 50 parts by mass, and most preferably 0.1 to 5 parts by mass per 100 parts by mass of the sum of components (B) and (C). If the content of component (D) is below the recommended lower limit, this will impair handleability of the composition, if components (B) and (C) are added in an increased quantity. If, on the other hand, component (D) is added in an amount exceeding the recommended lower limit, this will impair physical strength of a cured product of the composition.

Component (E) is a silane compound or product of its partial hydrolysis and condensation. The use of component (E) in combination with component (D) for obtaining a silicone composition of high thermal conductivity makes it possible to add components (B) and (C) in increased amounts without impairing handleability of the obtained composition. Silane compound of component (E) is represented by the following general formula:

R⁵ₑSi(OR⁶)₍₄₋ₑ₎

In this formula, R⁵ represents univalent hydrocarbon groups, epoxy-containing organic groups, methacryl-containing organic groups, or acryl-containing organic groups. The univalent hydrocarbon groups of R⁵ can be represented by methyl, ethyl, propyl, butyl, hexyl, decyl, or similar linear-chain alkyl groups; isopropyl, tertiary butyl, isobutyl, or similar branched-chain alkyl groups; cyclohexyl, or similar cyclic alkyl groups; vinyl, allyl, butenyl, pentenyl, hexenyl, heptenyl, or similar alkenyl groups; phenyl, tolyl, xylyl, or similar aryl groups; benzyl, phenethyl, or similar aralkyl groups; and 3,3,3-trifluoropropyl, 3-chloropropyl, or similar halogenated alkyl groups. The epoxy-containing organic groups of R⁵ can be represented by 3-glycidoxypropyl and 2-(3,4-epoxycyclohexyl)ethyl groups. The methacryl-containing organic groups of R⁵ can be represented by 3-methacryloxypropyl groups. The acryl-containing organic groups of R⁵ can be represented by 3-acryloxypropyl groups. In the above formula, R⁶ represents alkyl groups or alkoxyalkyl groups which can be exemplified by the same alkyl or alkoxyalkyl groups as those defined above for R³. In addition, “e” in the above formula is an integer ranging from 1 to 3, preferably 1 or 2, and most preferably 1.

The aforementioned silane compound that constitutes component (E) can be exemplified by methyltrimethoxysilane, methyltriethoxysilane, ethyltrimethoxysilane, n-propyltrimethoxysilane, butyltrimethoxysilane, pentyltrimethoxysilane, vinyltrimethoxysilane, vinyltriethoxysilane, methylvinyldimethoxysilane, allyltrimethoxysilane, allylmethyldimethoxysilane, butenyltrimethoxysilane, 3-glycidoxypropyltrimethoxysilane, 3-glycidoxypropylmethyldimethoxysilane, 3-glycidoxypropyltriethoxysilane, 3-methacryloxypropyl-trimethoxysilane, 3-methacryloxypropyltriethoxysilane, and 3-methacryloxypropylmethyldimethoxysilane, 3-acryloxypropylmethyldimethoxysilane.

Component (E) can be added to the composition in an amount of 0.005 to 10 parts by mass, preferably 0.01 to 10 parts by mass, and most preferably 0.01 to 5 parts by mass per 100 parts by mass of the sum of components (B) and (C). If component (E) is added in an amount less than the recommended lower limit, then addition of components (B) and (C) in increased quantities will either impair handleability of the obtained silicone composition, or will cause precipitation and separation of component (B) or component (C) during storage of the obtained silicone composition. If, on the other hand, the added amount of component (E) exceeds the recommended upper limit, this will increase the components that do not contribute to surface-treating of components (B) and (C).

Examples of methods for treating the surfaces of components (B) and (C) with components (D) and (E) are the following: a method consisting of pre-treating the surfaces of components (B) and (C) with component (D) and then treating with component (E); a method consisting of pre-treating the surface of components (B) and (C) with component (E) and then treating with component (D); a method consisting of treating the surfaces of components (B) and (C) simultaneously with components (D) and (E); a method consisting of pre-treating the surface of components (B) and (C) with component (D) in component (A) and then treating with component (E); a method consisting of pre-treating the surface of components (B) and (C) with component (E) in component (A) and then treating with component (D); a method consisting of treating the surfaces of components (B) and (C) simultaneously with components (D) and (E) in component (A); a method consisting of pre-treating the surface of components (B) and (C) with component (D) and then with component (E) in component (A); and a method consisting of pre-treating the surface of components (B) and (C) with component (E) and then with component (D) in component (A). In the compositions obtained by the above-described methods, the surfaces of components (B) and (C) are either treated with components (D) and (E) or remain untreated. In case the components (B) and (C) are surface treated with component (D) or (E), in order to accelerate the treatment, the process is carried out with heating or with the use of acetic acid, phosphoric acid, or a similar acidic substances, or trialkylamine, quaternary ammonium salt, gaseous ammonia, or ammonium carbonate added in catalytic quantities.

When the organopolysiloxane of component (A) in the composition of the invention contains in one molecule silicon-bonded alkenyl groups on average in the quantity of 0.1 or more, preferably 0.5 or more, even more preferably 0.8 or more, and most preferably 2 or more, then the addition of a curing agent makes the composition curable.

The curing agent may be represented by (F) an organopolysiloxane having in one molecule on average two or more silicon-bonded hydrogen atoms and by (G) a platinum-based catalyst. If the organopolysiloxane that constitutes component (F) contains in one molecule on average two or more silicon-bonded hydrogen atoms, there are no special restrictions with regard to the positions where such hydrogen atoms are bonded, and the bonding position may be located on the molecular terminals, in side chains, or in both. Silicon-bonded groups of component (F), other than hydrogen atoms, may be represented by univalent hydrocarbon groups, which are free of unsaturated aliphatic bonds, such as methyl, ethyl, propyl, butyl, pentyl, hexyl, or similar alkyl groups; cyclopentyl, cyclohexyl, or similar cyclic alkyl groups; phenyl, tolyl, xylyl, or similar aryl groups; benzyl, phenethyl, or similar aralkyl groups; and 3,3,3-trifluoropropyl, 3-chloropropyl, or similar halogenated alkyl groups. Most preferable are alkyl and aryl groups, especially methyl and phenyl groups. There are no special restrictions with regard to the molecular structure of the organopolysiloxane of component (F). For example, the structure can be linear, branched, partially branched linear, cyclic, or dendritic. Suggested organopolysiloxanes of component (F) that have the aforementioned molecular structure include, e.g., a homopolymer, copolymer or a mixture of these polymers. In addition, although there are no limitations concerning the viscosity of the organopolysiloxane at 25° C., it is preferably in the range of from 1 to 100,000 mPa·s, preferably, in the range of from 1 to 10,000 mPa·s, and most preferably, in the range of 1 to 5,000 mPa·s.

Aforementioned component (F) may be exemplified by the following compounds: a methylhydrogenpolysiloxane capped at both molecular terminals with trimethylsiloxy groups; a copolymer of a methylhydrogensiloxane and a dimethylsiloxane capped at both molecular terminals with trimethylsiloxy groups; a dimethylpolysiloxane capped at both molecular terminals with dimethylhydrogensiloxy groups; a methylhydrogenpolysiloxane capped at both molecular terminals with dimethylhydrogensiloxy groups; a copolymer of methylhydrogensiloxane and dimethylsiloxane capped at both molecular terminals with dimethylhydrogensiloxy groups; a cyclic methylhydrogenpolysiloxane, and an organosiloxane composed of siloxane units represented by the following unit formulae: (CH₃)₃SiO_{1/2}, (CH₃)₂HSiO_{1/2}, and SiO_{4/2}; tetra(dimethylhydrogensiloxy)silane, and a methyl-tri(dimethylhydrogensiloxy)silane.

Component (F) can be added to the composition in such an amount that the content of silicon-bonded hydrogen atoms of this component ranges from 0.1 to 10 moles, preferably 0.1 to 5 moles, and most preferably, 0.1 to 3 moles per 1 mole of silicon-bonded alkenyl groups contained in component (A). If component (F) is added in an amount less than the recommended lower limit, it will be difficult to cure the composition to a required degree. If, on the other hand, the added amount of component (F) exceeds the recommended upper limit, this will facilitate liberation of gaseous hydrogen from a cured product of the composition.

The platinum type metal based catalyst that constitutes component (G) is added to the composition for acceleration of curing. Such a catalyst can be exemplified by chloroplatinic acid, alcohol solutions of chloroplatinic acid, olefin complexes of platinum, alkenylsiloxane complexes of platinum, and carbonyl complexes of platinum. Catalysts of other types may be comprised of rhodium based catalysts or palladium based catalysts, but platinum based catalysts are preferable.

In the present composition, the content of component (G) is the content necessary for curing the composition. Specifically, it is sufficient to provide, in mass units, preferably between 0.01 ppm and 1,000 ppm, and particularly preferably between 0.1 ppm and 500 ppm of platinum type metal from the component relative to the amount of Component (A). This is due to the fact that when the content of the component is less than the recommended lower limit of the above-mentioned range, the resultant silicone composition tends to fail to completely cure, and, on the other hand, adding an amount exceeding the recommended upper limit of the above-mentioned range does not significantly improve the curing speed of the resultant silicone composition.

In order to adjust the curing speed of the present composition and improve its handleability, it is preferable to combine it with 2-methyl-3-butyn-2-ol, 2-phenyl-3-butyn-2-ol, 1-ethynyl-1-cyclohexanol, and other acetylene compounds; 3-methyl-3-penten-1-yne, 3,5-dimethyl-3-hexen-1-yne, and other eneyne compounds; and, in addition, hydrazine compounds, phosphine compounds, mercaptane compounds, and other curing reaction inhibitors. There are no limitations concerning the content of the curing reaction inhibitors, however, preferably it is in the range of from 0.0001 to 1.0 mass % relative to the amount of the present composition.

Furthermore, so long as the object of the present invention is not impaired, the present composition may contain other optional components, e.g., fumed silica, fused silica, precipitated silica, or other fine silica powders, or the aforementioned silica powders having surfaces hydrophobically treated with alkoxysilane, chlorosilane, silazane, or similar organic silicon compounds. There are no special restrictions with regard to the particle size of the fine silica powder, but it is recommended that the BET specific surface area be no less than 50 m²/g, and preferably no less than 100 m²/g.

The fine silica powder is added to the composition in an amount of 0.1 to 10 parts by mass, preferably 0.5 to 10 parts by mass per 100 parts by mass of component (A). If the content of the fine silica powder is below the recommended lower limit, the obtained composition will have very high flowability. If, on the other hand, the fine silica powder is added in an amount exceeding the recommended upper limit, this will noticeably impair handleability of the composition.

In order to improve adhesive properties on the surface of a product obtained by curing the composition of the invention, the latter may incorporate an adhesion-promoting agent. Such an agent may be exemplified, e.g., by a silatrane derivative represented by the formula given below, or a similar silatrane derivative that contains in one molecule at least one alkenyl group and at least one silicon-bonded alkoxy group:

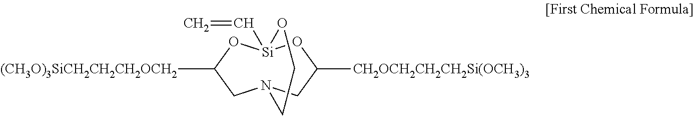

a siloxane compound that contains in one molecule at least one of each of the following groups: a silicon-bonded alkenyl group or a silicon-bonded hydrogen atom, a silicon-bonded alkoxy group, and an epoxy-containing organic group, a methacryl-containing organic group, or an acryl-containing organic group. More specifically, this may be a siloxane compound represented by the following average unit formula:

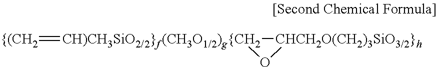

(where “f”, “g”, and “h” are positive numbers);
a siloxane compound represented by the following average unit formula:

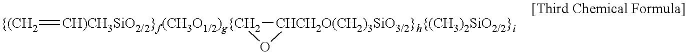

(where “f”, “g”, “h”, and “i” are positive numbers);
or a combination of two or more of the above compounds. The epoxy-containing organic groups, methacryl-containing organic groups, and acryl-containing organic groups contained in the aforementioned adhesion-promoting agents may be exemplified by the same groups of these types as those mentioned above. There are no restrictions with regard to amount in which the adhesion-promoting agents can be added to the composition, but it may be recommended to add them in an amount of 0.01 to 10 parts by mass per 100 parts by mass of component (A).

In addition to components (B) and (C), the composition can be combined with various thermally conductive fillers, such as, e.g., aluminum oxide, magnesium oxide, titanium oxide, beryllium oxide, or a similar metal oxide, except for zinc oxide; aluminum hydroxide, magnesium hydroxide, or a similar metal hydroxide; aluminum nitride, silicon nitride, boron nitride, or similar nitride; boron carbide, titanium carbide, silicon carbide, or similar carbide; graphite; copper, nickel, silver, or similar metals, except for aluminum; or mixtures of the above.

Within the limits not contrary to the object of the invention, the composition may incorporated such arbitrary components as pigments, dyes, fluorescent dyes, heat resistant agents, triazole compounds, and other flame retardants, and plasticizing agents.

The composition may be produced in the form of greases, pastes, or clays. If the composition is to be curable, there are no limitations with regard to the method that can be used for curing the composition. For example, the composition can be cured by retaining at room temperature after the composition is formed. Alternatively, the composition can be cured by heating at a temperature of 50° C. to 200° C. after the formation. There are no special restrictions with regard to the form in which a cured silicone product obtained from the composition can be produced. For example, the cured product may be in the form of gel, soft rubber, or hard rubber. The cured silicone product may have a density sufficient for employing this product as a heat-dissipating member.

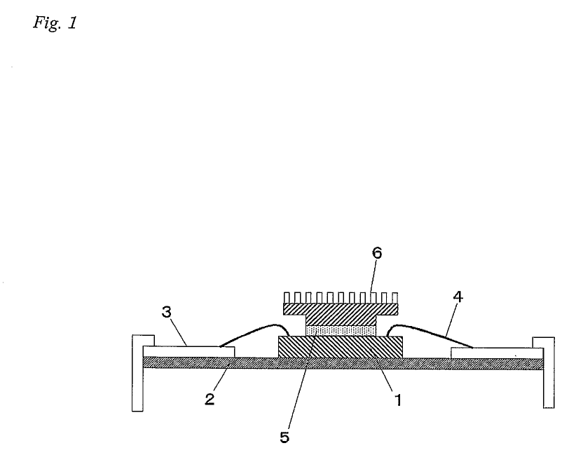

An LSI as an example of a semiconductor device of the invention will now be described with reference to FIG. 1. This device contains a semiconductor chip 1 placed onto a circuit board 2. The circuit 3 of the circuit board 2 is electrically connected to the semiconductor chip 1 by bonding wires 4. A heat-dissipating member 6 is attached to the semiconductor chip 1 via a thermally conductive silicone composition of the invention or via a cured body of the aforementioned composition 5. In other words, in the structure of the semiconductor device of the invention, the heat generated during operation by the semiconductor chip 1 is transmitted to the heat-dissipating member 6 through the thermally conductive silicone composition of the invention or a cured body of the composition. The thermally conductive silicone composition or a cured body of this composition 5, which, as shown in FIG. 1, is sandwiched between the semiconductor chip 1 and the heat-dissipating member 6, is characterized by high reliability, since it is not subject to oil bleeding even when operating under severe temperature conditions.

### EXAMPLES

The thermally conductive silicone composition and the semiconductor device of the invention will now be described in more details with reference to practical examples. In these examples, all values of viscosity refer to viscosities at 25° C. The following methods were used for evaluating characteristics of the thermally conductive silicone composition of the invention and of a cured body of the composition.

### [Viscosity of the Thermally Conductive Silicone Composition]

Viscosity of the thermally conductive silicone composition at 25° C. was measured by means of a rheometer (Model AR550, the product of TA Instruments, Ltd.). The geometry comprised parallel plates having a diameter of 20 mm. Measurement was carried out under the following conditions: a gap of 200 μm, a shear rate of 10.0 (1/s).

### [Thermal Conductivity of the Thermally Conductive Silicone Composition]

The thermally conductive silicone composition was placed into a 60 mm×150 mm×25 mm container, and, after defoaming, the surface of the composition was coated with a polyvinylidene chloride film having a thickness of 10 μm. Following this, thermal conductivity of the thermally conductive silicone composition was measured by means of a hot-wire method with the use a high-speed heat-conductivity meter (operating on the heat ray principle) of the Kyoto Denshi Kogyo Co., Ltd.

### [Thermal Conductivity of a Cured Body of the Thermally Conductive Silicone Composition]

The thermally conductive silicone composition was subjected to pressure curing for 15 min. at a temperature of 150° C., and the obtained cured body, having dimensions of 50 mm×100 mm×20 mm, was then heated for 1 hour in an oven at 150° C. Thermal conductivity of the cured body was measured by the hot-wire method using a Quick Thermal Conductivity Meter, QTM-500 Model, manufactured by Kyoto Denshi Kogyo Co., Ltd.

### [Tensile Shear Adhesive Strength of a Cured Body of the Thermally Conductive Silicone Composition]

The thermally conductive silicone composition was sandwiched and squeezed between two aluminum (A1050P) plates so that the composition layer had a thickness of 1 mm and other dimensions of 25 mm×10 mm. In this condition, the composition was cured by heating for 1 hour at 150° C., whereby a specimen was produced. The obtained specimen was tested according to JIS K 6850 with regard to the tensile shear adhesive strength by using the universal testing machine Tensilon (Model RTC-1325A; the product of Orientech Co., Ltd.).

### [Handleability of the Thermally Conductive Silicone Composition]

The thermally conductive silicone composition was loaded into a 30 ml polypropylene-made syringe (needle diameter=0.90 mm), a coating test was conducted at 0.2 MPa, and the mass of the thermally conductive silicone composition expelled from the syringe during 10 sec. was measured. The handleability was considered good and marked by symbol (O) if the expelled amount was equal to or was greater than 30 mg and was considered insufficient and marked by symbol (X) if the expelled amount was less than 30 mg.

### Practical Example 1

A mixture was prepared by mixing the following components for 15 min. in a T.K. Highvismix® of Tokushu Kika Kogyo Co., Ltd. at room temperature: 12.0 parts by mass of a dimethylpolysiloxane capped at both molecular terminals with dimethylvinylsiloxy groups (viscosity=10,000 mPa·s; vinyl group content=0.135 mass %); 50.0 parts by mass of a spherical aluminum powder having an average particle diameter equal to 8 μm; 20 parts by mass of a spherical aluminum powder having an average particle diameter equal to 2 μm; 15.0 parts by mass of a zinc oxide powder having an average particle size equal to 0.1 μm; 1 part by mass of a dimethylpolysiloxane of the following formula:

CH₂═CH(CH₃)₂SiO[(CH₃)₂SiO]₂₇Si(OCH₃)₃,

and 0.4 parts by mass of methyltrimethoxysilane. The mixture was additionally mixed for 1 hour at 150° C. under a reduced pressure below −0.09 MPa, and, after cooling to room temperature, a thermally conductive silicone composition was obtained.

The obtained thermally conductive silicone composition was further mixed with 2.7 parts by mass of a copolymer of a methylhydrogensiloxane and a dimethylsiloxane capped at both molecular terminals with trimethylsiloxy groups and having in one molecule on average 3 silicon-bonded hydrogen atoms (viscosity=5.5 mPa·s; content of silicon-bonded hydrogen atoms=0.13 mass %) (amount of silicon-bonded hydrogen atoms contained in this component was 1.5 moles per 1 mole of vinyl groups of dimethylpolysiloxane contained in the thermally conductive silicone composition); 0.005 parts by mass of a curing inhibitor in the form of 2-phenyl-3-butyn-2-ol; and 1.0 part by mass of a siloxane compound represented by the following average unit formula:

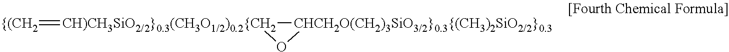

The obtained mixture was further combined and mixed for 15 min. at room temperature with 0.1 parts by mass of a platinum complex of 1,3-divinyl-1,1,3,3-tetramethyldisiloxane that contained 0.5 mass % of platinum, and a curable thermally conductive silicone composition was obtained.

### Practical Example 2

A mixture was prepared by mixing the following components for 15 min. in a T.K. Highvismix® of Tokushu Kika Kogyo Co., Ltd. at room temperature: 6.0 parts by mass of a dimethylpolysiloxane capped at both molecular terminals with dimethylvinylsiloxy groups (viscosity=2,000 mPa·s; vinyl group content=0.22 mass %); 50.0 parts by mass of roundish aluminum powder particles having an average particle diameter equal to 9 μm; 25.0 parts by mass of roundish aluminum powder having an average particle diameter equal to 2 μm; 16.0 parts by mass of a zinc oxide powder having an average particle size equal to 0.1 μm; 4.0 parts by mass of a dimethylpolysiloxane of the following formula:

CH₂═CH(CH₃)₂SiO[(CH₃)₂SiO]₃Si(OCH₃)₃,

and 0.5 parts by mass of methyltrimethoxysilane. The mixture was additionally mixed for 1 hour at 150° C. under a reduced pressure below −0.09 MPa, and, after cooling to room temperature, a thermally conductive silicone composition was obtained.

### Practical Example 3

A mixture was prepared by mixing the following components for 15 min. in a T.K. Highvismix® of Tokushu Kika Kogyo Co., Ltd. at room temperature: 12.6 parts by mass of a dimethylpolysiloxane capped at both molecular terminals with dimethylvinylsiloxy groups (viscosity=2,000 mPa·s; vinyl group content=0.22 mass %); 45.0 parts by mass of a spherical aluminum powder having an average particle diameter equal to 8 μm; 23.0 parts by mass of a spherical aluminum powder having an average particle diameter equal to 2 μm; 14.0 parts by mass of a zinc oxide powder having an average particle size equal to 0.1 μm; 2.0 part by mass of fumed silica hydrophobically surface treated with hexamethyldisilazane (BET specific surface area=200 m²/g); 1.8 parts by mass of a dimethylpolysiloxane of the following formula:

CH₂═CH(CH₃)₂SiO[(CH₃)₂SiO]₂₇Si(OCH₃)₃,

and 0.4 parts by mass of methyltriethoxysilane. The mixture was additionally mixed for 1 hour at 150° C. under a reduced pressure below −0.09 MPa, and, after cooling to room temperature, a thermally conductive silicone composition was obtained.

The obtained thermally conductive silicone composition was further mixed with 0.5 parts by mass of a copolymer of a methylhydrogensiloxane and a dimethylsiloxane capped at both molecular terminals with trimethylsiloxy groups (viscosity=20 mPa·s; content of silicon-bonded hydrogen atoms=0.7 mass %) (amount of silicon-bonded hydrogen atoms contained in this component was 1.5 moles per 1 mole of vinyl groups of dimethylpolysiloxane contained in the thermally conductive silicone composition); 0.005 parts by mass of a curing inhibitor in the form of 2-phenyl-3-butyn-2-ol; and 1.0 part by mass of a siloxane compound represented by the following average unit formula (viscosity=25 mPa·s):

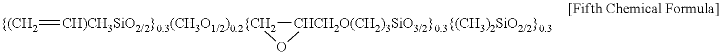

The obtained mixture was further combined and mixed for 15 min. at room temperature with 0.1 parts by mass of a platinum complex of 1,3-divinyl-1,1,3,3-tetramethyldisiloxane that contained 0.5 mass % of metallic platinum, and a curable thermally conductive silicone composition was obtained.

### Practical Example 4

A mixture was prepared by mixing the following components for 15 min. in a T.K. Highvismix® apparatus of Tokushu Kika Kogyo Co., Ltd. at room temperature: 2.0 parts by mass of a dimethylpolysiloxane capped at both molecular terminals with trimethylsiloxy groups (viscosity=200 mPa·s); 51.0 parts by mass of spherical aluminum powder particles having an average particle diameter equal to 8 μm; 26.0 parts by mass of spherical aluminum powder particles having an average particle diameter equal to 2 μm; 18.0 parts by mass of a zinc oxide powder having an average particle size equal to 0.1 μm; 3.5 parts by mass of a dimethylpolysiloxane of the following formula:

(CH₃)₃SiO[(CH₃)₂SiO]₁₁₀Si(OCH₃)₃,

and 0.4 parts by mass of methyltrimethoxysilane. The mixture was additionally mixed for 1 hour at 150° C. under a reduced pressure below −0.09 MPa, and, after cooling to room temperature, a thermally conductive silicone composition was obtained.

### Comparative Example 1

A mixture was prepared by mixing the following components for 15 min. in a T.K. Highvismix® of Tokushu Kika Kogyo Co., Ltd. at room temperature: 12.0 parts by mass of a dimethylpolysiloxane capped at both molecular terminals with dimethylvinylsiloxy groups (viscosity=10,000 mPa·s; vinyl group content=0.135 mass %); 50 parts by mass of a spherical aluminum powder having an average particle diameter equal to 8 μm; 20.0 parts by mass of a spherical aluminum powder having an average particle diameter equal to 2 μm; 15.0 parts by mass of a zinc oxide powder having an average particle size equal to 0.1 μm; and 1.0 part by mass of methyltrimethoxysilane. The mixture was additionally mixed for 1 hour at 150° C. under a reduced pressure below −0.09 MPa, and, after cooling to room temperature, a thermally conductive silicone composition was obtained.

The obtained thermally conductive silicone composition was further mixed with 2.7 parts by mass of a copolymer of a methylhydrogensiloxane and a dimethylsiloxane capped at both molecular terminals with trimethylsiloxy groups and having in one molecule on average 3 silicon-bonded hydrogen atoms (viscosity=5.5 mPa·s; content of silicon-bonded hydrogen atoms=0.13 mass %) (amount of silicon-bonded hydrogen atoms contained in this component was 1.5 moles per 1 mole of vinyl groups of dimethylpolysiloxane contained in the thermally conductive silicone composition); 0.005 parts by mass of a curing inhibitor in the form of 2-phenyl-3-butyn-2-ol; and 1.0 part by mass of a siloxane compound represented by the following average unit formula (viscosity=25 mPa·s):

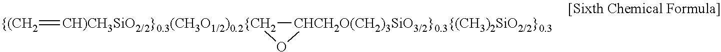

The obtained mixture was further combined and mixed for 15 min. at room temperature with 0.1 parts by mass of a platinum complex of 1,3-divinyl-1,1,3,3-tetramethyldisiloxane that contained 0.5 mass % of platinum, and a curable thermally conductive silicone composition was obtained.

### Comparative Example 2

A mixture was prepared by mixing the following components for 15 min. in a T.K. Highvismix® of Tokushu Kika Kogyo Co., Ltd. at room temperature: 14.4 parts by mass of a dimethylpolysiloxane capped at both molecular terminals with dimethylvinylsiloxy groups (viscosity=10,000 mPa·s; vinyl group content=0.135 mass %); 55.0 parts by mass of a spherical aluminum powder having an average particle diameter equal to 8 μm; 28.0 parts by mass of a spherical aluminum powder having an average particle diameter equal to 2 μm; 1.0 part by mass of a dimethylsiloxane of the following formula:

CH₂═CH(CH₃)₂SiO[(CH₃)₂SiO]₂₇Si(OCH₃)₃,

and 0.5 parts by mass of methyltrimethoxysilane. The mixture was additionally mixed for 1 hour at 150° C. under a reduced pressure below −0.09 MPa, and, after cooling to room temperature, a thermally conductive silicone composition was obtained.

The obtained thermally conductive silicone composition was further mixed with 0.5 parts by mass of a copolymer of a methylhydrogensiloxane and a dimethylsiloxane capped at both molecular terminals with trimethylsiloxy groups (viscosity=20 mPa·s; content of silicon-bonded hydrogen atoms=0.7 mass %) (amount of silicon-bonded hydrogen atoms contained in this component was 1.5 moles per 1 mole of vinyl groups of dimethylpolysiloxane contained in the thermally conductive silicone composition); 0.005 parts by mass of a curing inhibitor in the form of 2-phenyl-3-butyn-2-ol; and 1.0 part by mass of a siloxane compound represented by the following average unit formula:

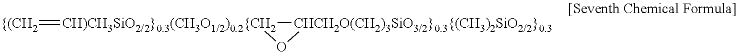

The obtained mixture was further combined and mixed for 15 min. at room temperature with 0.1 parts by mass of a platinum complex of 1,3-divinyl-1,1,3,3-tetramethyldisiloxane that contained 0.5 mass % of platinum, and a curable thermally conductive silicone composition was obtained.

### Comparative Example 3

A mixture was prepared by mixing the following components for 15 min. in a T.K. Highvismix® of Tokushu Kika Kogyo Co., Ltd. at room temperature: 5.0 parts by mass of a dimethylpolysiloxane capped at both molecular terminals with trimethylsiloxy groups (viscosity=200 mPa·s); 51.0 parts by mass of a spherical aluminum powder having an average particle diameter equal to 8 μm; 26.0 parts by mass of a spherical aluminum powder having an average particle diameter equal to 2 μm; 18.0 parts by mass of a zinc oxide powder having an average particle diameter equal to 0.1 μm; and 0.4 parts by mass of methyltrimethoxysilane. The mixture was additionally mixed for 1 hour at 150° C. under a reduced pressure below −0.09 MPa, and, after cooling to room temperature, a thermally conductive silicone composition was obtained.

TABLE 1

| | Examples | | | | | | |
|---|---|---|---|---|---|---|---|
| | Practical Examples | | | | Comparative Examples | | |
| Characteristics | 1 | 2 | 3 | 4 | 1 | 2 | 3 |
| Viscosity (Pa · s) | 130 | 97 | 140 | 82 | Impossible | 420 | 420 |
| | | | | | to measure | | |
| Thermal | 2.5 | 3.1 | 2.2 | 6.0 | 2.5 | 6.0 | 6.2 |
| Conductivity | | | | | | | |
| (W/m · K) | | | | | | | |
| Tensile Shear | 175 | — | 180 | — | Impossible | 250 | — |
| Adhesive | | | | | to measure | | |
| Strength | | | | | | | |
| (N/cm²) | | | | | | | |
| Handleability | ◯ | ◯ | ◯ | ◯ | X | X | X |

### INDUSTRIAL APPLICABILITY

Since the thermally conductive silicone composition of the invention possesses high thermal conductivity and excellent handleability, it can be used as a heat-dissipating member, e.g., for electronic assemblies that contain heat-emitting devices or for electronic parts of automobiles which operate under high-temperature conditions.

1. A thermally conductive silicone composition comprising:
(A) 100 parts by mass of an organopolysiloxane having a viscosity equal to or greater than 100 mPa·s at 25° C.;
(B) 25 to 4,500 parts by mass of aluminum powder having an average size of particles ranging from 0.1 to 100 μm;
(C) 10 to 1,000 parts by mass of zinc oxide powder having an average size of particles ranging from 0.05 to 50 μm;
(D) (i) an organopolysiloxane represented by the following general formula:
[R¹ₐR²₍₃₋ₐ₎SiO(R¹_{b}R²_{(2-b)}SiO)ₘ(R²₂SiO)ₙ]_{c}SiR²_{[4-(c+d)]}(OR³)_{d}
(where R¹ represents univalent hydrocarbon groups which have unsaturated aliphatic bonds; R² represents univalent hydrocarbon groups which are free of unsaturated aliphatic bonds; R³ represents groups selected from alkyl groups, alkoxyalkyl groups, alkenyl groups, or acyl groups; “a” is an integer ranging from 0 to 3; “b” is 1 or 2; “c” is an integer ranging from 1 to 3; “d” is an integer ranging from 1 to 3; “(c+d)” is an integer ranging from 2 to 4; “m” is an integer equal to or greater than 0; “n” is an integer equal to or greater than 0; however, when “a” is equal to 0, “m” is an integer equal to or greater than 1); and/or (ii) an organopolysiloxane represented by the following general formula:
R²₃SiO(R²₂SiO)ₚR²₂Si—R⁴—SiR²_{(3-d)}(OR³)_{d}
(where R², R³, and “d” are the same as defined above, R⁴ represents an oxygen atom or bivalent hydrocarbon group; and “p” is an integer ranging from 100 to 500) {this component being used in an amount of 0.01 to 100 parts by mass per 100 parts by mass of the sum of components (B) and (C)}; and
(E) a silane compound of the following general formula or a product of partial hydrolyzation and condensation of said silane compound:
R⁵ₑSi(OR⁶)₍₄₋ₑ₎
(where R⁵ represents univalent hydrocarbon groups, epoxy-containing organic groups, methacryl-containing organic groups, or acryl-containing organic groups; R⁶ represents alkyl groups or alkoxyalkyl groups; and “e” is an integer ranging from 1 to 3) {this component being used in an amount of 0.001 to 10 parts by mass per 100 parts by mass of the sum of components (B) and (C)}.

2. The thermally conductive silicone composition according to claim 1, wherein component (A) is an organopolysiloxane containing in one molecule on average 0.1 or more silicon-bonded alkenyl groups.

3. The thermally conductive silicone composition according to claim 2, further comprising:
(F) an organopolysiloxane having in one molecule two or more silicon-bonded hydrogen atoms {this component being used in such an amount that the content of the silicon-bonded hydrogen atoms contained in this component ranges from 0.1 to 10 moles per 1 mole of the silicon-bonded alkenyl groups contained in component (A)}; and
(G) a platinum type metal based catalyst {this component being used in such an amount that, in terms of mass units, the content of platinum type metal in this component ranges from 0.01 to 1,000 ppm per mass of the sum of components (A) and (F)}.

4. The thermally conductive silicone composition according to claim 1, wherein component (B) comprises a mixture prepared from aluminum powders of at least two types that have a difference in average particle sizes equal to or greater than 5 μm.

5. The thermally conductive silicone composition according to claim 1, wherein, in terms of mass units, the ratio of component (B) to component (C) ranges from 0.1 to 9.9.

6. A semiconductor device containing a semiconductor chip attached to or coated with a thermally conductive silicone composition according to claim 1.

7. The thermally conductive silicone composition according to claim 1, wherein component (D) is comprised of a mixture of constituents (i) and (ii) in a mass-unit ratio of 1:5 to 5:1.

8. The thermally conductive silicone composition according to claim 1, wherein, in constituent (i),
R¹ represents vinyl, allyl, or hexenyl groups,
R² represents alkyl or aryl groups, and
R³ represents groups selected from
methyl, ethyl, or propyl groups,
methoxyethoxy, ethoxyethoxy, or methoxypropoxy groups,
linear-chain alkenyl groups, or acetoxy groups; and
“a” is 1; “b” is 1; “c” is 1; and “d” is 3.

9. The thermally conductive silicone composition according to claim 1, wherein, in constituent (ii), R² represents linear-chain alkyl groups, R⁴ represents an oxygen atom; and “p” ranges from 110 to 500.

10. The thermally conductive silicone composition according to claim 7, wherein, in constituent (i), R¹ represents vinyl, allyl, or hexenyl groups, R² represents alkyl or aryl groups, and R³ represents groups selected from methyl, ethyl, or propyl groups, methoxyethoxy, ethoxyethoxy, or methoxypropoxy groups, linear-chain alkenyl groups, or acetoxy groups; “a” is 1; “b” is 1; “c” is 1; and “d” is 3; and wherein, in constituent (ii), R² represents linear-chain alkyl groups, R⁴ represents an oxygen atom; and “p” ranges from 110 to 500.

11. The thermally conductive silicone composition according to claim 1, wherein
R⁵ represents
linear-chain alkyl, branched-chain alkyl, alkenyl, aralkyl, or halogenated alkyl groups,
3-glycidoxypropyl or 2-(3,4-epoxycyclohexyl)ethyl groups,
3-methacryloxypropyl groups, or
3-acryloxypropyl groups;
R⁶ represents
methyl, ethyl, or propyl groups, or
methoxyethoxy, ethoxyethoxy, or methoxypropoxy groups; and
“e” is 1 or 2.
